(19) United States
(12) Patent Application Publication
(10) Pub. No.: US 2024/0363521 A1
(43) Pub. Date: Oct. 31, 2024

(54) SEMICONDUCTOR INTEGRATED CIRCUIT DEVICE

(71) Applicant: Socionext Inc., Kanagawa (JP)

(72) Inventor: Hideyuki KOMURO, Yokohama-shi, Kanagawa (JP)

(21) Appl. No.: 18/763,697

(22) Filed: Jul. 3, 2024

Related U.S. Application Data
(63) Continuation of application No. PCT/JP2022/047451, filed on Dec. 22, 2022.

(30) Foreign Application Priority Data
Jan. 6, 2022 (JP) 2022-001012

(51) Int. Cl. H01L 23/50; H01L 27/02; H01L 27/088

(52) U.S. Cl. CPC H01L 23/50; H01L 27/0207; H01L 27/088

(57) ABSTRACT

In a semiconductor integrated circuit device using buried power lines, a standard cell includes: a first buried power line extending in the X direction and supplying a first power supply voltage; a second buried power line extending in the X direction and supplying a second power supply voltage; and a first transistor connected to the first power line. The first buried power line is spaced from the first transistor in planar view and located closer to the center of the standard cell than the first transistor in the Y direction.

### CROSS-REFERENCE TO RELATED APPLICATIONS

This is a continuation of International Application No. PCT/JP2022/047451 filed on Dec. 22, 2022, which claims priority to Japanese Patent Application No. 2022-001012 filed on Jan. 6, 2022. The entire disclosures of these applications are incorporated by reference herein.

### BACKGROUND

The present disclosure relates to a semiconductor integrated circuit device using buried power rails (BPRs).

As a method for forming a semiconductor integrated circuit on a semiconductor substrate, a standard cell method is known. The standard cell method is a method in which basic units (e.g., inverters, latches, flipflops, and full adders) having specific logical functions are prepared in advance as standard cells, and a plurality of such standard cells are placed on a semiconductor substrate and connected through interconnects, thereby designing an LSI chip.

For higher integration of a semiconductor integrated circuit, it is proposed to use, for standard cells, interconnects laid in a buried interconnect layer, not interconnects laid in a metal interconnect layer formed above transistors as conventionally done.

U.S. Pat. No. 10,170,413 (FIG. 2C) discloses a technique of using interconnects laid in a buried interconnect layer not only as power lines (buried power rails (BPRs)) but also as signal lines.

Since buried power rails (BPRs) are interconnects buried in a substrate, they are not allowed to be laid in regions where transistors are placed in planar view. In the cited patent document, in which buried power rails are laid along upper and lower ends of a standard cell, it is unable to place transistors at the upper and lower ends of the standard cell. This makes it difficult to increase the transistor size.

An objective of the present disclosure is providing a semiconductor integrated circuit device using buried power lines, in which the size of transistors in standard cells can be easily increased.

### SUMMARY

According to the first mode of the present disclosure, a semiconductor integrated circuit device includes a plurality of standard cells, wherein a first standard cell, one of the plurality of standard cells, includes a first power line laid in a buried interconnect layer, extending in a first direction, and supplying a first power supply voltage, a second power line laid in the buried interconnect layer, extending in the first direction, and supplying a second power supply voltage, and a first transistor of a first conductivity type connected to the first power line, and the first power line is spaced from the first transistor in planar view and located closer to a center of the first standard cell than the first transistor in a second direction perpendicular to the first direction.

According to the above mode, in the first standard cell, the first power line laid in the buried interconnect layer is spaced from the first transistor connected to the first power line in planar view and located closer to the center of the first standard cell than the first transistor in the second direction. Therefore, the range of the first transistor can be expanded toward the outside of the first standard cell in the second direction. Thus, the size of the first transistor can be easily increased.

According to the second mode of the present disclosure, a semiconductor integrated circuit device includes a plurality of standard cells, wherein a first standard cell, one of the plurality of standard cells, includes first and second power lines laid in a buried interconnect layer, extending in a first direction, and supplying a first power supply voltage, third and fourth power lines laid in the buried interconnect layer, extending in the first direction, located between the first power line and the second power line in a second direction perpendicular to the first direction, and supplying a second power supply voltage, and a first transistor of a first conductivity type connected to the third power line, and the first transistor is spaced from the third and fourth power lines in planar view and located between the third power line and the fourth power line in the second direction.

According to the above mode, in the first standard cell, the third and fourth power lines are laid in the buried interconnect layer between the first power line and the second power line in the second direction and supply the second power supply voltage. The first transistor connected to the third power line is spaced from the third and fourth power lines in planar view and located between the third power line and the fourth power line in the second direction. Therefore, the range of the first transistor can be expanded in the space between the third power line and the fourth power line in the second direction. Thus, the size of the first transistor can be easily increased.

According to the third mode of the present disclosure, a semiconductor integrated circuit device includes a plurality of standard cells, wherein the plurality of standard cells include a first standard cell, and a second standard cell, the first standard cell includes a first power line laid in a buried interconnect layer, extending in a first direction, and supplying a first power supply voltage, and a first transistor of a first conductivity type connected to the first power line, the first power line is spaced from the first transistor in planar view, the second standard cell is adjacent to the first standard cell in a second direction perpendicular to the first direction and smaller in size in the second direction than the first standard cell, the second standard cell includes a second power line laid in the buried interconnect layer, extending in the first direction, and supplying the first power supply voltage, and the first transistor of the first standard cell is located between the first power line and the second power line in the second direction.

According to the above mode, the first and second standard cells are adjacent to each other in the second direction. In the first standard cell, the first power line laid in the buried interconnect layer is spaced from the first transistor connected to the first power line in planar view. The second standard cell includes the second power line laid in the buried interconnect layer, and the first transistor of the first standard cell is located between the first power line and the second power line in the second direction. Therefore, the range of the first transistor can be expanded toward the second standard cell in the second direction. Thus, the size of the first transistor can be easily increased.

According to the present disclosure, in a semiconductor integrated circuit device using buried power lines, the size of transistors in standard cells can be easily increased.

### BRIEF DESCRIPTION OF THE DRAWINGS

FIG. 1 is a plan view showing a block layout example of a semiconductor integrated circuit device according to the first embodiment.

FIG. 2 is a plan view showing a layout example of a cell SCA in FIG. 1.

FIGS. 3A and 3B are cross-sectional views showing cross-sectional structures of FIG. 2.

FIG. 4 is a circuit diagram of an inverter.

FIG. 5 is a plan view showing a layout example of a cell SCB in FIG. 1.

FIGS. 6A and 6B are plan views showing other layout examples of the cell SCB.

FIG. 7A is a plan view showing a layout example of a cell SCC in FIG. 1, and FIG. 7B is a plan view showing a layout example of the cells SCA and SCC adjacent to each other.

FIGS. 8A, 8B, and 8C are plan views showing other layout examples of upper/lower end cells.

FIG. 9 is a plan view showing a block layout example of a semiconductor integrated circuit device according to the second embodiment.

FIG. 10 is a plan view showing a layout example of a cell SCA2 in FIG. 9.

FIGS. 11A and 11B are plan views showing layout examples of a cell SCB2 in FIG. 9.

FIG. 12 is a plan view showing a layout example of the cell SCA2 and a cell SCC2 adjacent to each other in FIG. 9.

FIGS. 13A, 13B, and 13C are plan views showing other layout examples of upper/lower end cells.

FIGS. 14A and 14B are plan views showing layout examples of cells according to alterations of the second embodiment.

### DETAILED DESCRIPTION

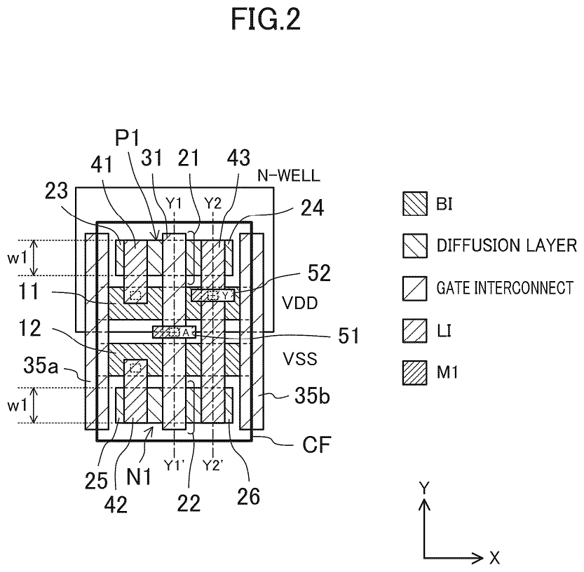

Embodiments of the present disclosure will be described hereinafter with reference to the accompanying drawings. Note that, in the following description, in the plan views such as FIG. 2, the horizontal direction in the figure is called an X direction (corresponding to the first direction), the vertical direction in the figure is called a Y direction (corresponding to the second direction), and the direction perpendicular to the substrate plane is called a Z direction (corresponding to the depth direction). Also, “VDD” indicates a power supply voltage, a high-voltage side power supply itself, or a high-voltage side power line, and “VSS” indicates a power supply voltage, a low-voltage side power supply itself, or a low-voltage side power line. Note also that standard cells are herein simply referred to as “cells” as appropriate. As used herein, a “dummy transistor” refers to a transistor that does not contribute to the logical function of a standard cell, and a “dummy gate interconnect” refers to a gate interconnect that does not constitute a transistor.

### First Embodiment

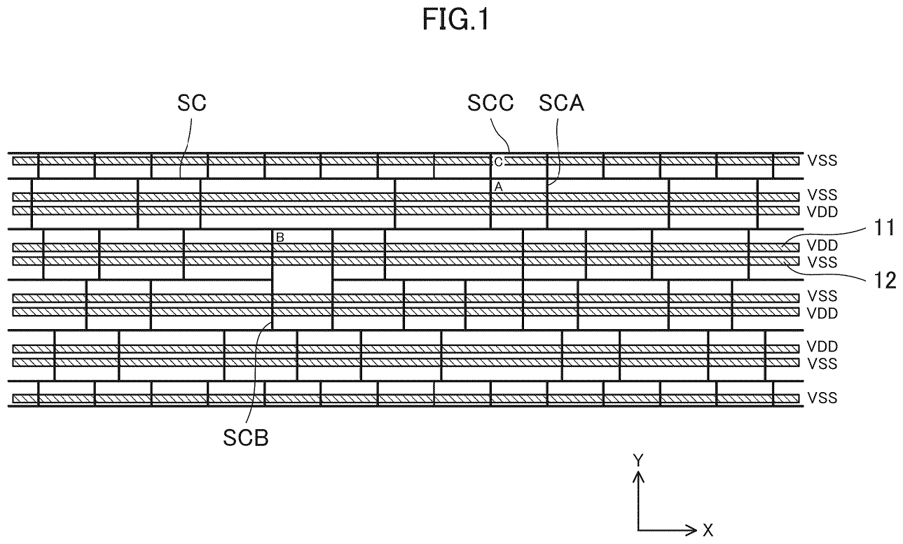

FIG. 1 is a plan view showing a block layout example of a semiconductor integrated circuit device according to the first embodiment. In the block layout of FIG. 1, a plurality of standard cells SC are arranged in the X direction and the Y direction. Note that, in FIG. 1, only power lines formed in a buried interconnect layer (BI) are illustrated.

In FIG. 1, buried power lines 11 supplying VDD to the standard cells SC and buried power lines 12 supplying VSS to the standard cells SC extend in the X direction. The standard cells SC receive VDD from the buried power lines 11 and VSS from the buried power lines 12. In cell rows other than the uppermost row and the lowermost row in the figure, among the cell rows shown in FIG. 1, the buried power lines 11 and 12 are laid in the center portion of each of the cell rows in the Y direction. Note that the standard cells in the cell rows are inverted vertically in the figure every cell row, and with this inversion, the positions of the buried power lines 11 and 12 are changed with each other in the Y direction every cell row. In the uppermost row and the lowermost row in the figure, only the buried power line 12 is laid in the center portion of each cell row in the Y direction.

The plurality of standard cells SC include standard cells SCA, SCB, and SCC. The standard cell SCA is a normal single-height cell, including a pair of buried power lines 11 and 12 in the cell. The standard cell SCB is a double-height cell, having a height (size in the Y direction) double that of the single-height cell and including two pairs of buried power lines 11 and 12 in the cell. The standard cell SCC is an upper/lower end cell, placed in the uppermost or lowermost cell row. The standard cell SCC has a height half the single-height cell and includes the buried power line 12.

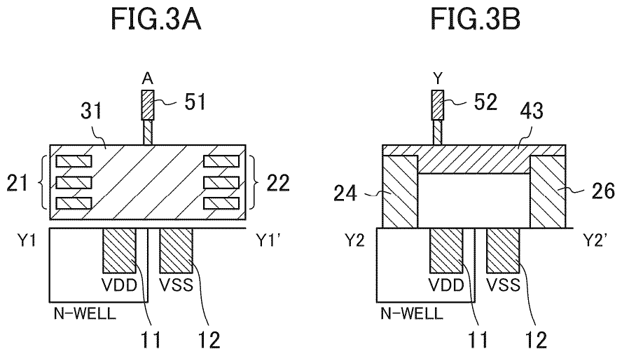

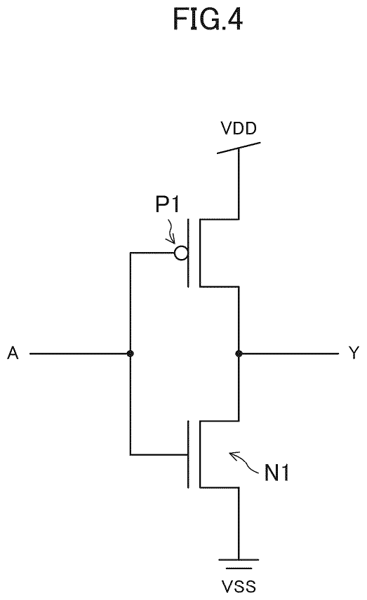

FIG. 2 is a plan view showing a layout example of the standard cell SCA, FIG. 3A is a cross-sectional view showing a cross-sectional structure taken along line Y1-Y1′ in FIG. 2, and FIG. 3B is a cross-sectional view showing a cross-sectional structure taken along line Y2-Y2′ in FIG. 2. The cell SCA shown in FIG. 2 constitutes an inverter shown in FIG. 4 as an example of a logic circuit. In the present disclosure, however, the logic circuit constituted by each standard cell is not limited to an inverter.

As shown in FIG. 2, in the cell SCA, the buried power lines 11 and 12 extending in the X direction are laid in the center portion in the Y direction. The buried power line 11 supplies VDD and the buried power line 12 supplies VSS. Note that, in the block layout of FIG. 1, the cell SCA is placed in a vertically inverted position in the figure. In FIG. 2, the boundaries of the cell SCA are indicated as a cell frame CF. This also applies to the other figures showing layout examples.

A p-type transistor P1 is formed on an N-well, and an n-type transistor N1 is formed on a P-well or a p-type substrate. The transistors P1 and N1 are arranged in a line in the Y direction. The transistors P1 and N1 have nanosheets 21 and 22, respectively, each made of three sheets, as channel portions. That is, the transistors P1 and N1 are nanosheet FETs. The number of nanosheets of each nanosheet FET is not limited to three. The regions of the nanosheets 21 and 22 constitute the channel regions of the transistors P1 and N1, respectively.

Pads 23 and 24 each made of a semiconductor layer of an integral structure connected to the three sheets are respectively formed on the left and right sides of the nanosheets 21 in the figure. The pad 23 is to be the source region of the transistor P1, and the pad 24 is to be the drain region of the transistor P1. Pads 25 and 26 each made of a semiconductor layer of an integral structure connected to the three sheets are respectively formed on the left and right sides of the nanosheets 22 in the figure. The pad 25 is to be the source region of the transistor N1, and the pad 26 is to be the drain region of the transistor N1.

A gate interconnect 31 extending in the Y direction is formed. The gate interconnect 31 surrounds the peripheries of the nanosheets 21 of the transistor P1 and the nanosheets 22 of the transistor N1 in the Y and Z directions through gate insulating films (not shown). The gate interconnect 31 corresponds to the gates of the transistors P1 and N1. The gate widths of the transistors P1 and N1 are the same (w1), although they are not necessarily required to be the same. Dummy gate interconnects 35a and 35b are formed over the cell frame CF on both sides of the gate interconnect 31 in the X direction.

Local interconnects 41, 42, and 43 extending in the Y direction are formed in a local interconnect layer. The local interconnect 41 is connected to the pad 23 and also connected to the power line 11 through a via. The local interconnect 42 is connected to the pad 25 and also connected to the power line 12 through a via. The local interconnect 43 is connected to the pads 24 and 26.

Metal interconnects 51 and 52 extending in the X direction are formed in an M1 interconnect layer. The metal interconnect 51 corresponds to an input node A and is connected to the gate interconnect 31 through a contact. The metal interconnect 52 corresponds to an output node Y and is connected to the local interconnect 43 through a contact.

As shown in FIG. 2, the buried power lines 11 and 12 are laid apart from the transistors P1 and N1 as nanosheet FETs in planar view. The buried power lines 11 and 12 are laid in the center portion in the Y direction and located closer to the center of the cell SCA than the transistors P1 and N1, respectively, in the Y direction. Therefore, the transistors P1 and N1 can be expanded up to near the cell frame CF in the Y direction. For example, the transistors P1 and N1 can be made closest possible to other transistors in the adjacent cells in the Y direction within the bounds of retaining the design rules.

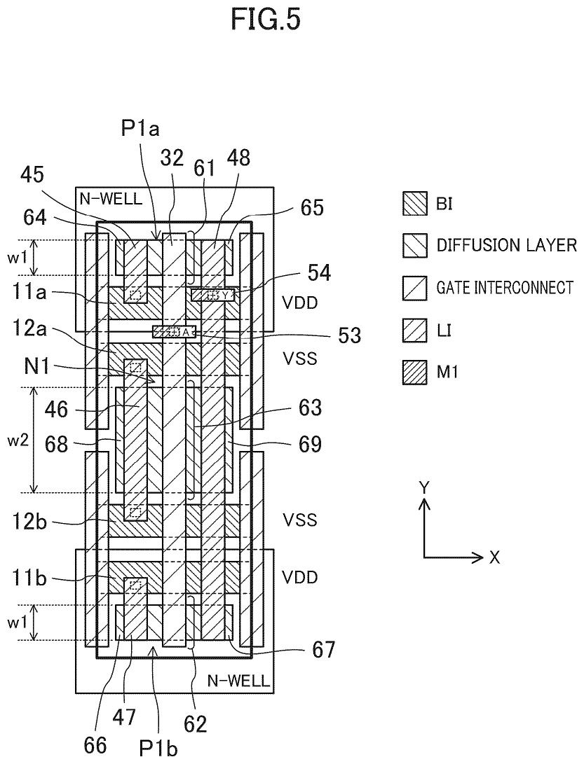

FIG. 5 is a plan view showing a layout example of the standard cell SCB. Like the cell SCA, the cell SCB shown in FIG. 5 constitutes the inverter shown in FIG. 4.

As shown in FIG. 5, in the center portion of the cell SCB in the Y direction, buried power lines 11a and 12a extending in the X direction are laid in an upper region in the figure, and buried power lines 11b and 12b extending in the X direction are laid in a lower region in the figure. The buried power lines 11a and 11b supply VDD and the buried power lines 12a and 12b supply VSS.

A p-type transistor P1a is formed on an upper N-well in the figure, and a p-type transistor P1b is formed on a lower N-well in the figure. The p-type transistors P1a and P1b constitute the transistor P1 in FIG. 4. An n-type transistor N1 is formed on a P-well or a p-type substrate. The transistors P1a, N1, and P1b are arranged in a line in the Y direction. The transistors P1a, P1b, and N1 have nanosheets 61, 62, and 63, respectively, each made of three sheets, for example, as channel portions. That is, the transistors P1a, P1b, and N1 are nanosheet FETs. The regions of the nanosheets 61, 62, and 63 constitute the channel regions of the transistors P1a, P1b, and N1, respectively.

Pads 64 and 65 each made of a semiconductor layer of an integral structure connected to the three sheets are respectively formed on the left and right sides of the nanosheets 61 in the figure. The pad 64 is to be the source region of the transistor P1a, and the pad 65 is to be the drain region of the transistor P1a. Pads 66 and 67 each made of a semiconductor layer of an integral structure connected to the three sheets are respectively formed on the left and right sides of the nanosheets 62 in the figure. The pad 66 is to be the source region of the transistor P1b, and the pad 67 is to be the drain region of the transistor P1b. Pads 68 and 69 each made of a semiconductor layer of an integral structure connected to the three sheets are respectively formed on the left and right sides of the nanosheets 63 in the figure. The pad 68 is to be the source region of the transistor N1, and the pad 69 is to be the drain region of the transistor N1. A gate interconnect 32 extending in the Y direction is formed. The gate interconnect 32 surrounds the peripheries of the nanosheets 61 of the transistor P1a, the nanosheets 62 of the transistor P1b, and the nanosheets 63 of the transistor N1 in the Y and Z directions through gate insulating films (not shown). The gate interconnect 32 corresponds to the gates of the transistors P1a, P1b, and N1. The gate widths of the transistors P1a and P1b are the same (w1), although they are not necessarily required to be the same. The gate width w2 of the transistor N1 is greater than double the gate width w1 of the transistors P1a and P1b (w2>w1×2).

Local interconnects 45, 46, 47, and 48 extending in the Y direction are formed in a local interconnect layer. The local interconnect 45 is connected to the pad 64 and also connected to the power line 11a through a via. The local interconnect 46 is connected to the pad 68 and also connected to the power lines 12a and 12b through vias. The local interconnect 47 is connected to the pad 66 and also connected to the power line 11b through a via. The local interconnect 48 is connected to the pads 65, 67, and 69.

Metal interconnects 53 and 54 extending in the X direction are formed in an M1 interconnect layer. The metal interconnect 53 corresponds to an input node A and is connected to the gate interconnect 32 through a contact. The metal interconnect 54 corresponds to an output node Y and is connected to the local interconnect 48 through a contact.

As shown in FIG. 5, the buried power lines 11a, 11b, 12a, and 12b are laid apart from the transistors P1a, P1b, and N1 as nanosheet FETs in planar view. The transistor N1 is located between the buried power lines 12a and 12b in the Y direction. Therefore, the range of the transistor N1 can be expanded in the space between the buried power lines 12a and 12b.

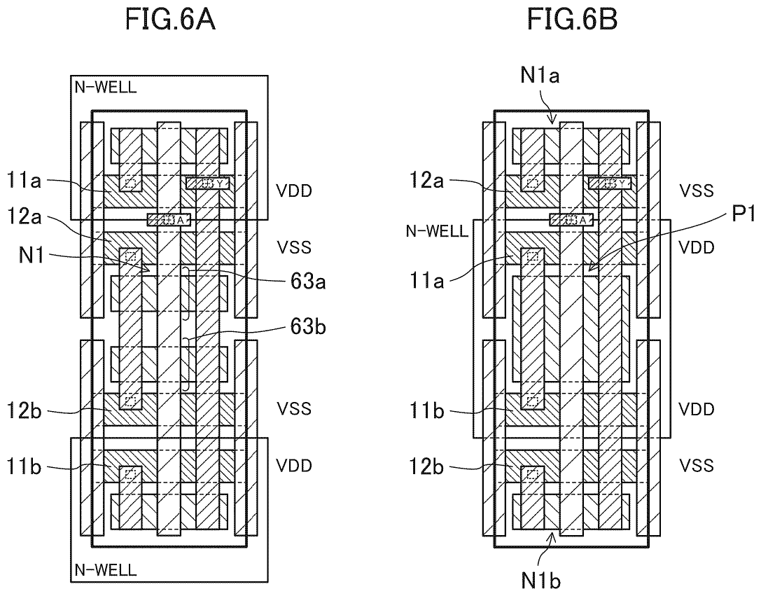

FIGS. 6A and 6B show other layout examples of the cell SCB. In the layout shown in FIG. 6A, the transistor N1 placed in the center portion in the Y direction has nanosheets 63a and 63b separated into two parts in the Y direction.

In the layout shown in FIG. 6B, the positions of the buried power lines 11a and 12a are changed with each other, and the positions of the buried power lines 11b and 12b are changed with each other. Also, transistors N1a and N1b are respectively placed near the upper and lower ends in the Y direction, and a transistor P1 is placed in the center portion in the Y direction. The n-type transistors N1a and N1b constitute the transistor N1 in FIG. 4. In the layout of FIG. 6B, the size of the transistor P1 can be increased in the space between the buried power lines 11a and 11b. Note that, in FIG. 6B, as in FIG. 6A, the transistor P1 placed in the center portion in the Y direction may have nanosheets separated into two parts in the Y direction.

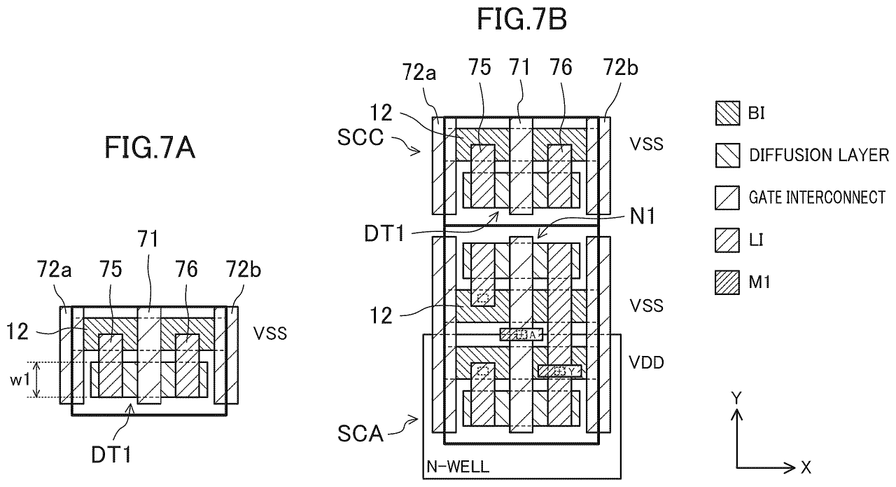

FIG. 7A is a plan view showing a layout example of the standard cell SCC as an upper/lower end cell, and FIG. 7B is a plan view showing the standard cells SCC and SCA adjacent to each other in the Y direction. In FIG. 7B, the cell SCA is placed in a position vertically inverted from the layout shown in FIG. 2 in the figure. As shown in FIG. 7B, the cell SCC is smaller in size in the Y direction than the cell SCA. Although the size of the cell SCC in the Y direction is illustrated here as a half of that of the cell SCA, it is not limited to this.

As shown in FIG. 7A, the standard cell SCC includes the power line 12 extending in the X direction and supplying VSS and a dummy transistor DT1. The dummy transistor DT1 has a gate interconnect 71 extending in the Y direction, and is connected to local interconnects 75 and 76 at its drain and source, respectively. Also, dummy gate interconnects 72a and 72b are formed over the cell frame on both sides of the gate interconnect 71 in the X direction.

As shown in FIG. 7B, the transistor N1 of the cell SCA is located between the power line 12 in the cell SCA and the power line 12 in the cell SCC. Also, with respect to the boundary between the cells SCA and SCC, the arrangement of the components, i.e., the buried power line, the transistor, the gate interconnect, and the local interconnects in the cell SCA and the arrangement of these components in the cell SCC are symmetric in the Y direction. In other words, the distances of the same components in the cells SCA and SCC from the boundary between the cells SCA and SCC are the same. Therefore, since the arrangement of the components becomes regular over the entire block layout of the semiconductor integrated circuit device, variations in the manufacture finishing of the components can be reduced.

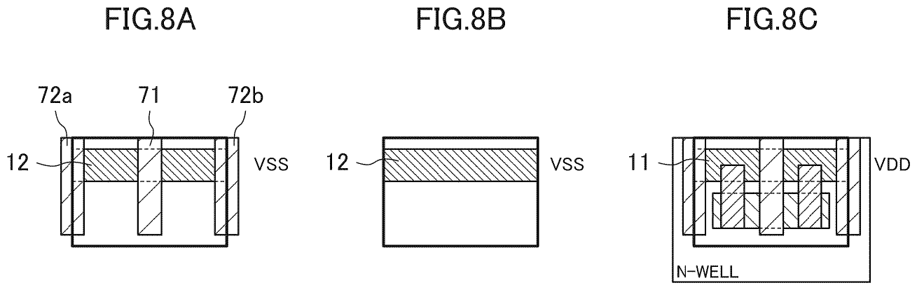

FIGS. 8A-8C are plan views showing other layout examples of the upper/lower end cell. FIG. 8A is an alteration of the layout of the cell SCC, having only the power line 12 and the dummy gate interconnects 71, 72a, and 72b. FIG. 8B is another alteration of the layout of the cell SCC, having only the power line 12.

FIG. 8C shows a layout example of an upper/lower end cell having the power line 11 supplying VDD. The upper/lower end cell of FIG. 8C is used when, in its adjacent cell in the Y direction, the transistor closest to the upper/lower end cell is a p-type transistor and the power line closest to the upper/lower end cell is a power line supplying VDD. In place of the layout of FIG. 8C, the cell may have a configuration having only the power line 11 and the dummy gate interconnects as in FIG. 8A. Also, the cell may have a configuration having only the power line as in FIG. 8B.

As described above, according to this embodiment, in the standard cell SCA, the buried power line 11 is spaced from the transistor P1 in planar view and located closer to the center of the cell SCA than the transistor P1 in the Y direction. Also, the buried power line 12 is spaced from the transistor N1 in planar view and located closer to the center of the cell SCA than the transistor N1 in the Y direction. Therefore, the ranges of the transistors P1 and N1 can be expanded toward the outside of the cell SCA in the Y direction. Thus, the sizes of the transistors P1 and N1 can be easily increased.

Also, in the standard cell SCB, the buried power lines 12a and 12b supplying VSS are placed between the buried power lines 11a and 11b supplying VDD in the Y direction. The transistor N1 is spaced from the buried power lines 12a and 12b in planar view and located between the buried power lines 12a and 12b in the Y direction. Therefore, the range of the transistor N1 can be expanded in the space between the buried power lines 12a and 12b in the Y direction. Thus, the size of the transistor N1 can be easily increased.

Moreover, the standard cells SCA and SCC are adjacent to each other in the Y direction. In the cell SCA, the buried power line 12 is spaced from the transistor N1 in planar view. Since the cell SCC as an upper/lower end cell has the buried power line 12, the transistor N1 of the cell SCA is located between the buried power lines 12 in the Y direction. Therefore, the range of the transistor N1 can be expanded toward the cell SCC in the Y direction. Thus, the size of the transistor N1 can be easily increased.

### Second Embodiment

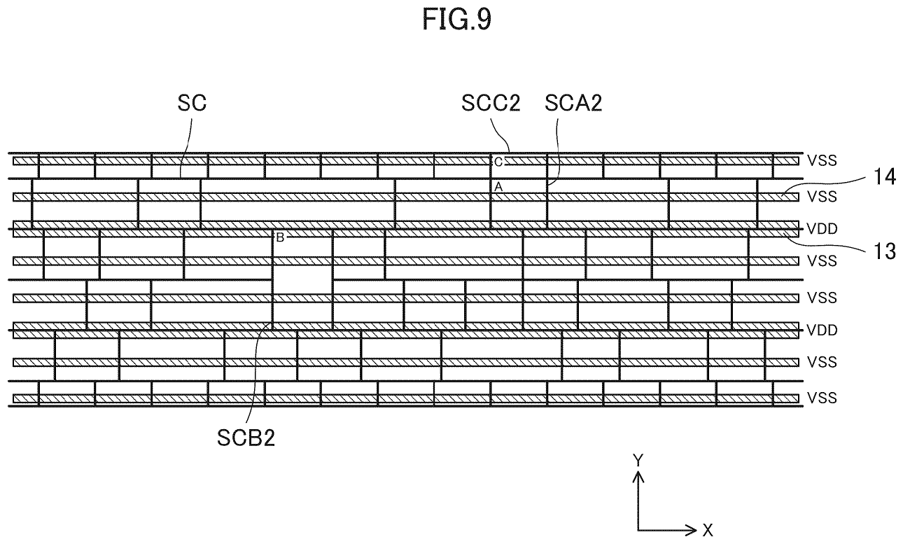

FIG. 9 is a plan view showing a block layout example of a semiconductor integrated circuit device according to the second embodiment. In the block layout of FIG. 9, a plurality of standard cells SC are arranged in the X and Y directions. The standard cells SC are inverted vertically in the figure every cell row. As in FIG. 1, only buried power lines formed in a buried interconnect layer (BI) are illustrated in FIG. 9.

In FIG. 9, buried power lines 13 supplying VDD to the standard cells SC and buried power lines 14 supplying VSS to the standard cells SC extend in the X direction. The standard cells SC receive VDD from the buried power lines 13 and VSS from the buried power lines 14.

In FIG. 9, the buried power lines 13 are laid over the boundaries of cell rows and shared by adjacent cells in the Y direction. The buried power lines 14 are laid in the center portions of the cell rows in the Y direction. The line width of the buried power lines 13 is greater than the line width of the buried power lines 14. For example, the line width of the buried power lines 13 is made double the line width of the buried power lines 11 shown in the first embodiment, whereby the same power line width as that in the first embodiment can be secured.

The plurality of standard cells SC include standard cells SCA2, SCB2, and SCC2. The standard cell SCA2 is a normal single-height cell, which includes the buried power line 13 supplying VDD laid along one end of the cell in the Y direction and the buried power line 14 supplying VSS laid in the cell. The standard cell SCB2 is a double-height cell, having a height double that of the single-height cell, which includes two buried power lines 13 supplying VDD each laid along each end of the cell in the Y direction and two buried power lines 14 supplying VSS laid in the cell. The standard cell SCC2 is an upper/lower end cell, placed in the uppermost or lowermost cell row. The standard cell SCC2 has a height half that of the single-height cell, and includes the buried power line 14 supplying VSS.

Note that, in the block layout of FIG. 9, it is also possible to lay the buried power lines supplying VSS over the boundaries of the cell rows and the buried power lines supplying VDD in the center portions of the cell rows in the Y direction.

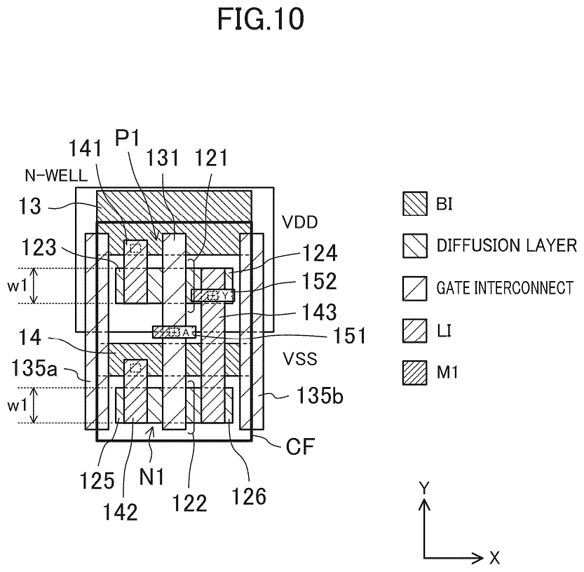

FIG. 10 is a plan view showing a layout example of the standard cell SCA2. The cell SCA2 shown in FIG. 10 constitutes an inverter shown in FIG. 4 as an example of a logic circuit. In the layout of FIG. 10, compared with the layout of FIG. 2 in the first embodiment, the positional relationship between the transistor P1 and the power line supplying VDD (power line 11 in FIG. 2, power line 13 in FIG. 10) is different.

As shown in FIG. 10, in the cell SCA2, the buried power line 13 extending in the X direction is laid along the upper end in the Y direction in the figure, and the buried power line 14 extending in the X direction is laid in the center portion in the Y direction. The buried power line 13 supplies VDD and the buried power line 14 supplies VSS. Note that, in the block layout of FIG. 9, the cell SCA2 shown in FIG. 10 is placed in a vertically inverted position in the figure.

A p-type transistor P1 is formed on an N-well, and an n-type transistor N1 is formed on a P-well or a p-type substrate. The transistors P1 and N1 are arranged in a line in the Y direction. The transistors P1 and N1 have nanosheets 121 and 122, respectively, each made of three sheets, for example, as channel portions. That is, the transistors P1 and N1 are nanosheet FETs. The number of nanosheets of each nanosheet FET is not limited to three. The regions of the nanosheets 121 and 122 constitute the channel regions of the transistors P1 and N1, respectively.

Pads 123 and 124 each made of a semiconductor layer of an integral structure connected to the three sheets are respectively formed on the left and right sides of the nanosheets 121 in the figure. The pad 123 is to be the source region of the transistor P1, and the pad 124 is to be the drain region of the transistor P1. Pads 125 and 126 each made of a semiconductor layer of an integral structure connected to the three sheets are respectively formed on the left and right sides of the nanosheets 122 in the figure. The pad 125 is to be the source region of the transistor N1, and the pad 126 is to be the drain region of the transistor N1.

A gate interconnect 131 extending in the Y direction is formed. The gate interconnect 131 surrounds the peripheries of the nanosheets 121 of the transistor P1 and the nanosheets 122 of the transistor N1 in the Y and Z directions through gate insulating films (not shown). The gate interconnect 131 corresponds to the gates of the transistors P1 and N1. The gate widths of the transistors P1 and N1 are the same (w1), although they are not necessarily required to be the same. Dummy gate interconnects 135a and 135b are formed over the cell frame CF on both sides of the gate interconnect 131 in the X direction.

Local interconnects 141, 142, and 143 extending in the Y direction are formed in a local interconnect layer. The local interconnect 141 is connected to the pad 123 and also connected to the power line 13 through a via. The local interconnect 142 is connected to the pad 125 and also connected to the power line 14 through a via. The local interconnect 143 is connected to the pads 124 and 126.

Metal interconnects 151 and 152 extending in the X direction are formed in an M1 interconnect layer. The metal interconnect 151 corresponds to an input node A and is connected to the gate interconnect 131 through a contact. The metal interconnect 152 corresponds to an output node Y and is connected to the local interconnect 143 through a contact.

As shown in FIG. 10, the buried power lines 13 and 14 are laid apart from the transistors P1 and N1 as nanosheet FETs in planar view. The buried power line 14 is laid in the center portion in the Y direction and located closer to the center of the cell SCA2 than the transistor N1 in the Y direction. Therefore, the transistor N1 can be expanded up to near the cell frame CF in the Y direction. For example, the transistor N1 can be made closest possible to a transistor of the adjacent cell in the Y direction on the lower side in the figure within the bounds of retaining the design rules. Also, since the power line 13 supplying VDD can be shared with the adjacent cell in the Y direction on the upper side in the figure, the power supply can be strengthened compared with the first embodiment.

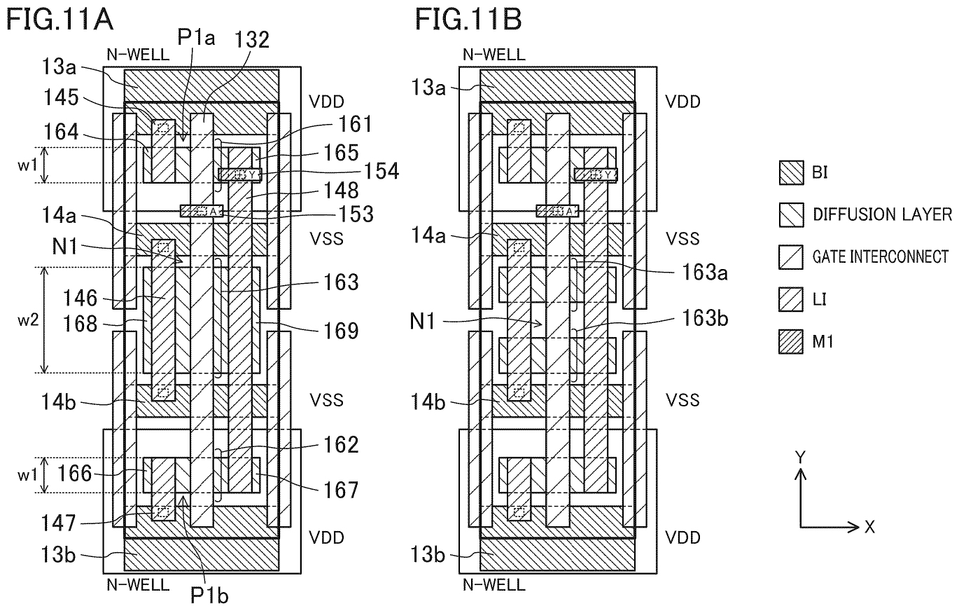

FIG. 11A is a plan view showing a layout example of the standard cell SCB2. Like the cell SCA2, the cell SCB2 shown in FIG. 11A constitutes an inverter shown in FIG. 4. In the layout of FIG. 11A, compared with the layout of FIG. 5 in the first embodiment, the positional relationship between the transistors P1a and P1b and the power lines supplying VDD (power lines 11a and 11b in FIG. 5, power lines 13a and 13b in FIG. 11A) is different.

As shown in FIG. 11A, in the cell SCB2, buried power lines 13a and 13b extending in the X direction are respectively laid along the upper and lower ends in the Y direction. Also, in the center portion of the cell SCB2 in the Y direction, a buried power line 14a extending in the X direction is laid in an upper region in the figure, and a buried power line 14b extending in the X direction is laid in a lower region in the figure. The buried power lines 13a and 13b supply VDD and the buried power lines 14a and 14b supply VSS.

A p-type transistor P1a is formed on an upper N-well in the figure, and a p-type transistor P1b is formed on a lower N-well in the figure. The p-type transistors P1a and P1b constitute the transistor P1 in FIG. 4. An n-type transistor N1 is formed on a P-well or a p-type substrate. The transistors P1a, N1, and P1b are arranged in a line in the Y direction. The transistors P1a, P1b, and N1 have nanosheets 161, 162, and 163, respectively, each made of three sheets, for example, as channel portions. That is, the transistors P1a, P1b, and N1 are nanosheet FETs. The regions of the nanosheets 161, 162, and 163 constitute the channel regions of the transistors P1a, P1b, and N1, respectively.

Pads 164 and 165 each made of a semiconductor layer of an integral structure connected to the three sheets are respectively formed on the left and right sides of the nanosheets 161 in the figure. The pad 164 is to be the source region of the transistor P1a, and the pad 165 is to be the drain region of the transistor P1a. Pads 166 and 167 each made of a semiconductor layer of an integral structure connected to the three sheets are respectively formed on the left and right sides of the nanosheets 162 in the figure. The pad 166 is to be the source region of the transistor P1b, and the pad 167 is to be the drain region of the transistor P1b. Pads 168 and 169 each made of a semiconductor layer of an integral structure connected to the three sheets are respectively formed on the left and right sides of the nanosheets 163 in the figure. The pad 168 is to be the source region of the transistor N1, and the pad 169 is to be the drain region of the transistor N1.

A gate interconnect 132 extending in the Y direction is formed. The gate interconnect 132 surrounds the peripheries of the nanosheets 161 of the transistor P1a, the nanosheets 162 of the transistor P1b, and the nanosheets 163 of the transistor N1 in the Y and Z directions through gate insulating films (not shown). The gate interconnect 132 corresponds to the gates of the transistors P1a, P1b, and N1. The gate widths of the transistors P1a and P1b are the same (w1), although they are not necessarily required to be the same. The gate width w2 of the transistor N1 is greater than double the gate width w1 of the transistors P1a and P1b (w2>w1×2).

Local interconnects 145, 146, 147, and 148 extending in the Y direction are formed in a local interconnect layer. The local interconnect 145 is connected to the pad 164 and also connected to the power line 13a through a via. The local interconnect 146 is connected to the pad 168 and also connected to the power lines 14a and 14b through vias. The local interconnect 147 is connected to the pad 166 and also connected to the power line 13b through a via. The local interconnect 148 is connected to the pads 165, 167, and 169.

Metal interconnects 153 and 154 extending in the X direction are formed in an M1 interconnect layer. The metal interconnect 153 corresponds to an input node A and is connected to the gate interconnect 132 through a contact. The metal interconnect 154 corresponds to an output node Y and is connected to the local interconnect 148 through a contact.

As shown in FIG. 11A, the buried power lines 13a, 13b, 14a, and 14b are laid apart from the transistors P1a, P1b, and N1 as nanosheet FETs in planar view. The transistor N1 is located between the buried power lines 14a and 14b in the Y direction. Therefore, the range of the transistor N1 can be expanded in the space between the buried power lines 14a and 14b.

FIG. 11B shows an alteration of the layout of the cell SCB shown in FIG. 11A. In the layout shown in FIG. 11B, the transistor N1 placed in the center portion in the Y direction has nanosheets 163a and 163b separated into two parts in the Y direction.

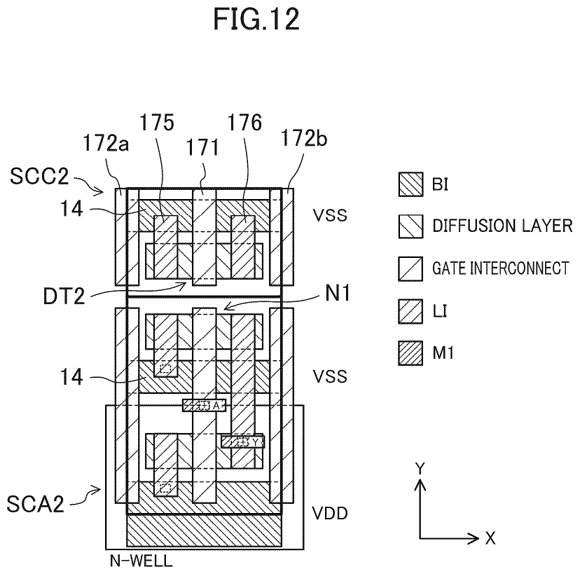

FIG. 12 is a plan view showing in combination the layouts of the standard cells SCC2 and SCA2 adjacent to each other in the Y direction. In FIG. 12, the cell SCA2 is placed in a position vertically inverted from the layout shown in FIG. 10 in the figure. As shown in FIG. 12, the cell SCC2 is smaller in size in the Y direction than the cell SCA2. Although the size of the cell SCC2 in the Y direction is illustrated here as a half of that of the cell SCA2, it is not limited to this.

As shown in FIG. 12, the layout of the standard cell SCC2 is the same as the layout of the cell SCC of FIG. 7A in the first embodiment. That is, the cell SCC2 includes the power line 14 extending in the X direction and supplying VSS and a dummy transistor DT2. The dummy transistor DT2 has a gate interconnect 171 extending in the Y direction, and is connected to local interconnects 175 and 176 at its drain and source, respectively. Also, dummy gate interconnects 172a and 172b are formed over the cell frame on both sides of the gate interconnect 171 in the X direction.

As shown in FIG. 12, the transistor N1 of the cell SCA2 is located between the power line 14 in the cell SCA2 and the power line 14 in the cell SCC2. Also, with respect to the boundary between the cells SCA2 and SCC2, the arrangement of the components, i.e., the buried power line, the transistor, the gate interconnect, and the local interconnects in the cell SCA2 and the arrangement of these components in the cell SCC2 are symmetric in the Y direction. In other words, the distances of the same components in the cells SCA2 and SCC2 from the boundary between the cells SCA2 and SCC2 are the same. Therefore, since the arrangement of the components becomes regular over the entire block layout of the semiconductor integrated circuit device, variations in the manufacture finishing of the components can be reduced.

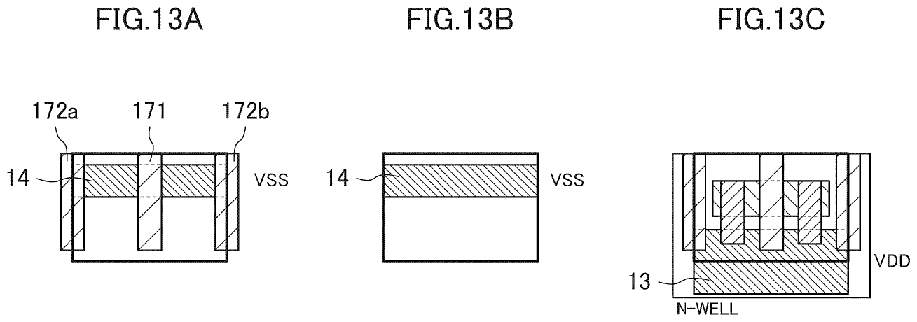

FIGS. 13A-13C are plan views showing other layout examples of the upper/lower end cell. FIG. 13A is an alteration of the layout of the cell SCC2, having only the power line 14 and the dummy gate interconnects 171, 172a, and 172b. FIG. 13B is another alteration of the layout of the cell SCC2, having only the power line 14.

FIG. 13C shows a layout example of the upper/lower end cell having the power line 13 supplying VDD. The upper/lower end cell of FIG. 13C is used when, in its adjacent cell in the Y direction, the power line closest to the upper/lower end cell is a power line supplying VDD laid along the cell end. That is, the upper/lower end cell of FIG. 13C shares the power line 13 with the cell adjacent in the Y direction on the lower side in the figure. In place of the layout of FIG. 13C, the cell may have a configuration having only the power line 13 and the dummy gate interconnects as in FIG. 13A. Also, the cell may have a configuration having only the power line as in FIG. 13B.

As described above, according to this embodiment, in the standard cell SCA2, the buried power line 14 is spaced from the transistor N1 in planar view and located closer to the center of the cell SCA2 than the transistor N1 in the Y direction. Therefore, the range of the transistor N1 can be expanded toward the outside of the cell SCA2 in the Y direction. Thus, the size of the transistor N1 can be easily increased.

Also, in the standard cell SCB2, the buried power lines 14a and 14b supplying VSS are placed between the buried power lines 13a and 13b supplying VDD in the Y direction. The transistor N1 is spaced from the buried power lines 14a and 14b in planar view and located between the buried power lines 14a and 14b in the Y direction. Therefore, the range of the transistor N1 can be expanded in the space between the buried power lines 14a and 14b. Thus, the size of the transistor N1 can be easily increased.

Moreover, the standard cells SCA2 and SCC2 are adjacent to each other in the Y direction. In the cell SCA2, the buried power line 14 is spaced from the transistor N1 in planar view. Since the cell SCC2 as an upper/lower end cell has the buried power line 14, the transistor N1 of the cell SCA2 is located between the buried power lines 14 in the Y direction. Therefore, the range of the transistor N1 can be expanded toward the cell SCC2 in the Y direction. Thus, the size of the transistor N1 can be easily increased.

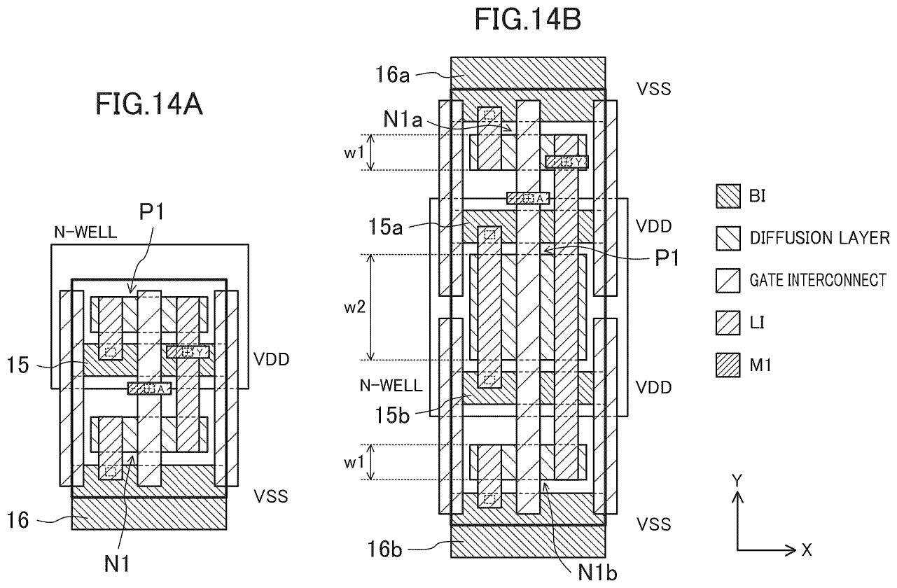

FIGS. 14A-14B show layout examples of cells according to alterations of the second embodiment. The layouts of FIGS. 14A-14B are used in a block layout in which buried power lines supplying VSS are laid over the boundaries of cell rows and buried power lines supplying VDD are laid in the center portions of the cell rows in the Y direction. FIG. 14A shows a layout example of a single-height cell, and FIG. 14B shows a layout example of a double-height cell.

In FIG. 14A, a buried power line 15 supplying VDD extending in the X direction is laid in the center portion in the Y direction, and a buried power line 16 supplying VSS extending in the X direction is laid along the lower end in the Y direction in the figure. The transistor P1 is placed on the upper side with respect to the buried power line 15 in the figure. The transistor N1 is placed between the buried power line 15 and the buried power line 16. The other configuration is similar to the layout of the cell SCA2 shown in FIG. 10. The buried power line 15 is laid in the center portion in the Y direction and located closer to the center of the cell than the transistor P1. Therefore, the transistor P1 can be expanded up to near the cell frame in the Y direction.

In FIG. 14B, in the center portion in the Y direction, a buried power line 15a extending in the X direction is laid in an upper region in the figure, and a buried power line 15b extending in the X direction is laid in a lower region in the figure. Also, buried power lines 16a and 16b extending in the X direction are respectively laid along the upper and lower ends in the Y direction. The buried power lines 15a and 15b supply VDD and the buried power lines 16a and 16b supply VSS.

A transistor P1 is placed between the buried power lines 15a and 15b in the center portion in the Y direction, a transistor N1a is placed between the buried power lines 15a and 16a, and a transistor N1b is placed between the buried power lines 15b and 16b. The n-type transistors N1a and N1b constitute the transistor N1 in FIG. 4. The other configuration is similar to the layout shown in FIG. 6B. In the layout of FIG. 14B, the size of the transistor P1 can be increased in the space between the buried power lines 15a and 15b. Note that, in FIG. 14B, the transistor P1 placed in the center portion in the Y direction may have nanosheets separated into two parts in the Y direction, as in FIG. 11B.

According to the present disclosure, in a semiconductor integrated circuit device using buried power lines, the size of transistors in standard cells can be easily increased. The present disclosure is therefore useful for improvement in the performance of system LSI.

1. A semiconductor integrated circuit device comprising a plurality of standard cells,
wherein
a first standard cell, one of the plurality of standard cells, includes
a first power line laid in a buried interconnect layer, extending in a first direction, and supplying a first power supply voltage,
a second power line laid in the buried interconnect layer, extending in the first direction, and supplying a second power supply voltage, and
a first transistor of a first conductivity type connected to the first power line, and
the first power line is spaced from the first transistor in planar view and located closer to a center of the first standard cell than the first transistor in a second direction perpendicular to the first direction.

2. The semiconductor integrated circuit device of claim 1, wherein
the first standard cell includes
a second transistor of a second conductivity type connected to the second power line, and
the second power line is spaced from the second transistor in planar view and located closer to the center of the first standard cell than the second transistor in the second direction.

3. The semiconductor integrated circuit device of claim 1, wherein
the first standard cell includes
a second transistor of a second conductivity type connected to the second power line, and
the second power line is spaced from the second transistor in planar view and located farther from the center of the first standard cell than the second transistor in the second direction.

4. A semiconductor integrated circuit device comprising a plurality of standard cells,
wherein
a first standard cell, one of the plurality of standard cells, includes
first and second power lines laid in a buried interconnect layer, extending in a first direction, and supplying a first power supply voltage,
third and fourth power lines laid in the buried interconnect layer, extending in the first direction, located between the first power line and the second power line in a second direction perpendicular to the first direction, and supplying a second power supply voltage, and
a first transistor of a first conductivity type connected to the third power line, and
the first transistor is spaced from the third and fourth power lines in planar view and located between the third power line and the fourth power line in the second direction.

5. The semiconductor integrated circuit device of claim 4, wherein
the first standard cell includes
a second transistor of a second conductivity type connected to the first power line, and
the first power line is spaced from the second transistor in planar view and located closer to a center of the first standard cell than the second transistor in the second direction.

6. The semiconductor integrated circuit device of claim 4, wherein
the first standard cell includes
a second transistor of a second conductivity type connected to the first power line, and
the first power line is spaced from the second transistor in planar view and located farther from a center of the first standard cell than the second transistor in the second direction.

7. The semiconductor integrated circuit device of claim 4, wherein
the first transistor is placed astride a center of the first standard cell in the second direction.

8. A semiconductor integrated circuit device comprising a plurality of standard cells,
wherein
the plurality of standard cells include
a first standard cell, and
a second standard cell,
the first standard cell includes
a first power line laid in a buried interconnect layer, extending in a first direction, and supplying a first power supply voltage, and
a first transistor of a first conductivity type connected to the first power line,
the first power line is spaced from the first transistor in planar view,
the second standard cell is adjacent to the first standard cell in a second direction perpendicular to the first direction and smaller in size in the second direction than the first standard cell,
the second standard cell includes
a second power line laid in the buried interconnect layer, extending in the first direction, and supplying the first power supply voltage, and
the first transistor of the first standard cell is located between the first power line and the second power line in the second direction.

9. The semiconductor integrated circuit device of claim 8, wherein
the second standard cell includes a dummy transistor.

10. The semiconductor integrated circuit device of claim 8, wherein
the first standard cell includes
a third power line laid in the buried interconnect layer, extending in the first direction, and supplying a second power supply voltage, and
a second transistor of a second conductivity type connected to the third power line, and
the third power line is spaced from the second transistor in planar view and located closer to a center of the first standard cell than the second transistor in the second direction.

11. The semiconductor integrated circuit device of claim 8, wherein
the first standard cell includes
a third power line laid in the buried interconnect layer, extending in the first direction, and supplying a second power supply voltage, and
a second transistor of a second conductivity type connected to the third power line, and
the third power line is spaced from the second transistor in planar view and located farther from a center of the first standard cell than the second transistor in the second direction.
